(19) United States
(12) Patent Application Publication
(10) Pub. No.: US 2013/0050977 A1
(43) Pub. Date: Feb. 28, 2013

(54) HOUSING AND PORTABLE ELECTRONIC DEVICE USING SAME

(71) Applicants: REN-BO WANG, Shenzhen City (CN); XIN-WU GUAN, Shenzhen City (CN); PO-FENG HO, Shindian (TW); WU-ZHENG OU, Shindian (TW)

(72) Inventors: REN-BO WANG, Shenzhen City (CN); XIN-WU GUAN, Shenzhen City (CN); PO-FENG HO, Shindian (TW); WU-ZHENG OU, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/421,306

(22) Filed: Mar. 15, 2012

(30) Foreign Application Priority Data
Aug. 22, 2011 (CN) 201120306322.0

(51) Int. Cl. H05K 7/00; B65D 85/00

(52) U.S. Cl. 361/820; 206/320

(57) ABSTRACT

A housing for a portable electronic device is transparent and U-shaped. The housing includes a first section, a second section opposite to the first section, and a connection portion connecting the first section to the second section.

### BACKGROUND

1. Technical Field

The disclosure relates to a housing and a portable electronic device employing the housing.

2. Description of Related Art

Mobile phones generally have only one display screen, that must serve several purposes such as displaying menus as well as images, resulting in limited viewing area.

Therefore, there is room for improvement within the art.

### BRIEF DESCRIPTION OF THE FIGURE

Many aspects of the housing and the portable electronic device can be better understood with reference to the following drawings. The components in the drawings are not necessarily drawn to scale, the emphasis instead being placed upon clearly illustrating the principles of the housing and the portable electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of an exemplary housing.

FIG. 2 is a top plan view of the housing of FIG. 1.

FIG. 3 is a schematic view of an exemplary portable electronic device employing the housing of FIG. 1.

### DETAILED DESCRIPTION

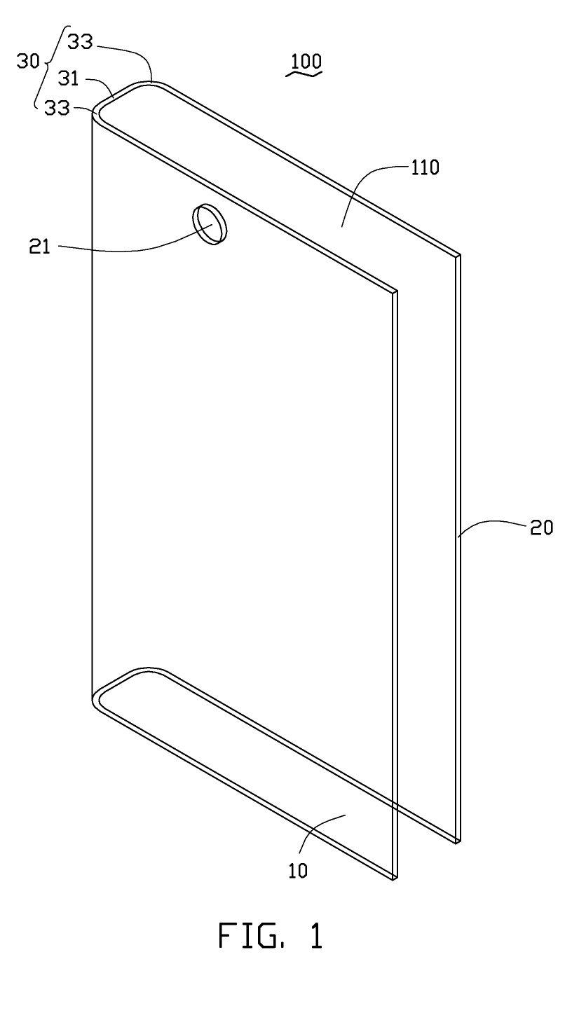

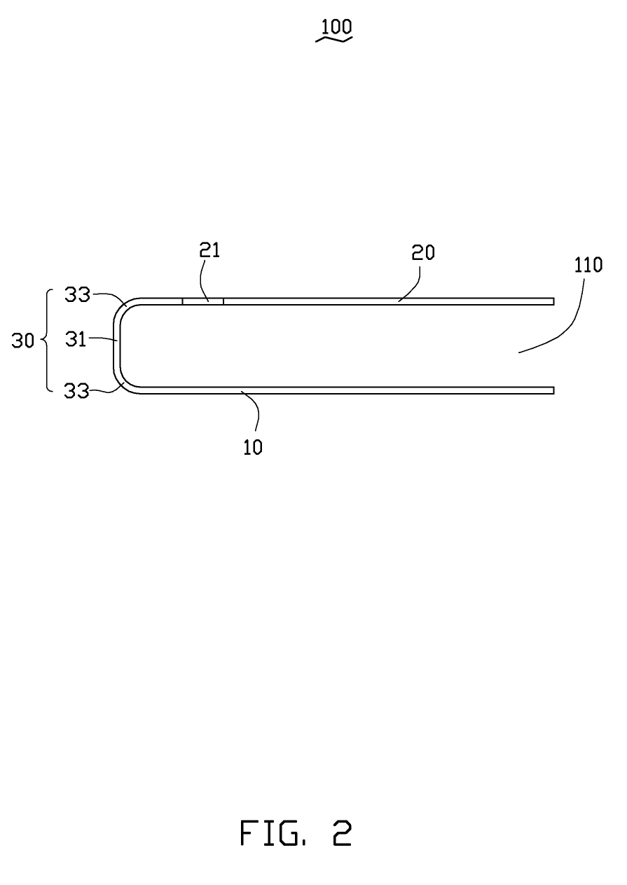

FIG. 1 and FIG. 2 show a housing 100 according to an exemplary embodiment. The housing 100 is transparent and is made of clear glass, transparent plastic, or transparent ceramic. The housing 100 may be used as a shell of a portable electronic device 300.

The housing 100 is approximately U-shaped, which includes a first section 10, a second section 20 opposite to the first section 10, and a connection portion 30 connecting the first section 10 and the second section 20. The first and the second section 10 and 20, and connection portion 30 may be used as display windows.

The first and the second section 10 and 20 are plate-shaped. The connection portion 30 includes a plate-shaped main body 31, and two arc-shaped extension portions 33 extending out from opposite ends of the main body 31. The two extension portions 33 connect to sides of the first and second sections 10 and 20, respectively.

The entire area of the first section 10 may be configured to display images. The entire area or just a portion of the area of the second section 20 may be configured to display images. A through hole 21 is defined in the second section 20, and the through hole 21 can be used to receive a camera (not shown).

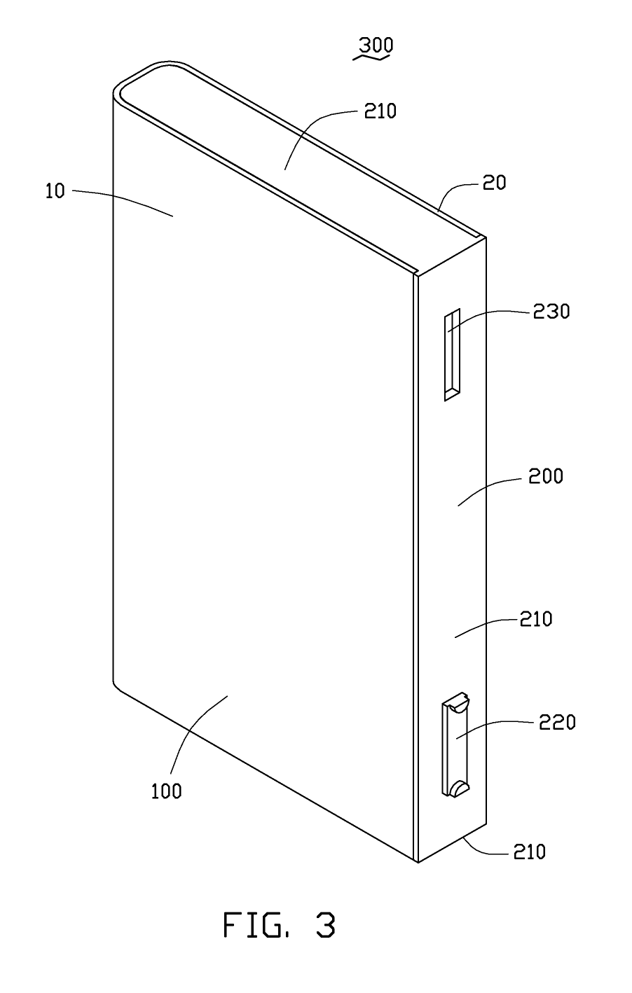

A receiving space 110 is formed in the housing 110. An electronic chip 200 is received in the receiving space 110, and the portable electronic device 300 shown in FIG. 3 is assembled. The electronic chip 200 is equipped with various functional modules to achieve various functions of the portable electronic device 300. The electronic chip 200 has three exposed sidewalls 210 when it is received in the receiving space 110. Functional button 220 and functional interface 230 can be set on the three sidewalls 210, such as a power button, a volume button, a power connector, and an USB data interface.

The first and the second section 10 and 20 of the housing 100 of the portable electronic device 300 greatly increase the video image display area. The housing 100 can also providing the functions of multiple display screens, expands the functions of and improves the appearance of the portable electronic device 300. The assembly of the portable electronic device 300 is simple and efficient.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing for a portable electronic device, the housing being transparent, comprising:
a first section;
a second section opposite to the first section; and
a connection portion connecting the first section to the second section to make the housing U-shaped.

2. The housing as claimed in claim 1, wherein the first and the second section are plate-shaped.

3. The housing as claimed in claim 1, wherein the connection portion comprises a plate-shaped main body and two arc-shaped extension portions extending from opposite ends of the main body.

4. The housing as claimed in claim 1, wherein the connection portion is a display window.

5. The housing as claimed in claim 1, wherein a through hole is defined in the second section, and the through hole is used to receive a camera.

6. The housing as claimed in claim 1, wherein the first section is a display window.

7. The housing as claimed in claim 1, wherein the second section is a display window.

8. A portable electronic device, comprising:
a housing and an electronic chip received in the housing,
wherein the housing is transparent and U-shaped, the housing comprises a first section, a second section opposite to the first section; and a connection portion connecting the first section to the second section.

9. The portable electronic device as claimed in claim 8, wherein the first and the second section are plate-shaped.

10. The portable electronic device as claimed in claim 8, wherein the connection portion comprises a plate-shaped main body and two arc-shaped extension portions extending from opposite ends of the main body.

11. The portable electronic device as claimed in claim 8, wherein the connection portion is a display window.

12. The portable electronic device as claimed in claim 8, wherein the first section is a display window.

13. The portable electronic device as claimed in claim 8, wherein the second section is a display window.

14. The portable electronic device as claimed in claim 8, wherein a receiving space is formed in the housing, the electronic chip is received in the receiving space.

15. The portable electronic device as claimed in claim 14, wherein the electronic chip has three exposed sidewalls when it is received in the receiving space, and functional buttons and functional interfaces are set on the three sidewalls.
